(19) United States
(12) Patent Application Publication
(10) Pub. No.: US 2004/0082186 A1
(43) Pub. Date: Apr. 29, 2004

(54) Method for cleaning plasma etching apparatus, method for plasma etching, and method for manufacturing semiconductor device

(76) Inventor: Satoru Okamoto, Isehara (JP)

Correspondence Address: FISH & RICHARDSON P.C., 1425 K STREET, N.W., 11TH FLOOR, WASHINGTON, DC, 20005-3500, US

(21) Appl. No.: 10/689,617

(22) Filed: Oct. 22, 2003

(30) Foreign Application Priority Data
Oct. 24, 2002 (JP) 2002-310257

(51) Int. Cl. H01L 21/302; H01L 21/461

(52) U.S. Cl. 438/709

(57) ABSTRACT

A method for manufacturing a semiconductor device wherein phenomenon called the skirting and dispersion in reliability of a TFT among lots can be reduced is provided by using a method for cleaning a plasma etching apparatus, a method for plasma etching, and a method for manufacturing a semiconductor device using the plasma etching method. Concretely, the plasma density may be kept constant by exciting plasma using a gas capable of etching quartz, for example, Cl₂, or a mixed gas of Cl₂ with a fluorine-based gas such as CF₄ after using an etching gas such as BCl₃ with which BOₓ adheres to the quartz surface and thus removing the BOₓ adhering to the quartz surface inside the chamber (that is, cleaning is performed).

### BACKGROUND OF THE INVENTION

1. Field of the Invention

The present invention relates to a method for cleaning a plasma etching apparatus and method for plasma etching. More specifically, the present invention relates to a method for manufacturing a semiconductor device in which the plasma etching method is used.

2. Description of the Related Art

According to miniaturization of a semiconductor element, a semiconductor device using the semiconductor element can be fabricated to be small-size, lightweight, low consumption, and high-speed. However, miniaturization of a thin film transistor (TFT) that is one of semiconductor devices involves a problem of low reliability due to of hot carrier effect.

Therefore, an LDD (Lightly Doped Drain) structure is adopted as a means of controlling hot carrier effect. The LDD structure is a structure in which regions having lower impurity concentration (LDD regions) than those of a source or a drain are provided between the source or the drain regions and a channel formation region.

Particularly, it is known that in the case of having a structure in which an LDD region is overlapped with a gate electrode through a gate insulating film (GOLD structure, Gate-drain Overlapped LDD structure), hot carrier effect can be efficiently prevented by relaxation of high electric field in the vicinity of the drain and reliability can be improved. It is noted that the region in which an LDD region is overlapped with a gate electrode through a gate insulating film is termed a Lov region and the region in which an LDD region is not overlapped with a gate electrode is termed a Loff region in this specification.

Several manufacturing methods of an LDD region are already proposed. As one of a manufacturing methods for not to increase the number of masks, a method by which an LDD region is formed in a self-aligning manner using a gate electrode which is formed of two layers having different width from each other is proposed. In this case, two layered gate electrode has different width from each other in an upper layer and a lower layer in a channel length direction, and then the gate electrode is formed by performing two times of etching generally in different conditions.

A structure of a TFT provided two layered gate electrode which has different width from each other in a channel length direction is given as an example in FIG. 7A. Reference numeral 6001 denotes an island shape semiconductor layer; reference numeral 6002 denotes a gate insulating film; and reference numeral 6003 denotes a gate electrode, respectively. The island shape semiconductor layer 6001 and the gate electrode 6003 are overlapped while the gate insulating film 6002 is sandwiched in between. The gate electrode 6003 is formed of an upper layer 6003a and a lower layer 6003b, which are formed of different materials with each other.

The semiconductor film 6001 has a channel formation region 6004, LDD regions 6005, and a source or a drain regions 6006. The LDD regions 6005 are provided between the channel formation region 6004 and the source or the drain regions 6006.

A width Wb in a channel length direction of a lower layer of the gate electrode 6003b is formed by anisotropic etching so as to have the longer width than a width Wa in the channel length direction of an upper layer of the gate electrode 6003a. Moreover, the LDD regions 6005 can be formed by utilizing difference in the width of the upper and the lower layers of gate electrode. In particular, acceleration speed is controlled when doping in order to dope impurities into a semiconductor film through the gate insulating 6002 and the lower layer of gate electrode 6003b. According to the above structure, an LDD region can be formed by doping impurities preferentially through a region of a lower layer 6003b of gate electrode which is not overlapped with the upper layer 6003a of the gate electrode over the semiconductor film 6001.

In general, plasma etching is used when a conductive film is anisotropically etched. It is necessary that an etching gas be properly selected according to a material of a conductive film.

Here, reference. 1, H. Kawada “An In Situ Analasis of Residue Deposited on an Etching Chamber's Surface” Plasma Science Symposium 2001/The 18th Symposium on Plasma Processing, SA2-2, PP. 241-242 describes using BCl₃ as an etching gas. In the reference, it is described that B₂O₃ was adhered to the surface of quartz provided within the chamber of the etching apparatus when BCl₃ is utilized as an etching gas

However, in the case where a TFT is manufactured according to the steps shown in FIGS. 7A and 7B, the upper layer of conductive film has been inadequately anisotropic etched in several lots in the plural number of lots even though etching is performed in the same condition. Therefore, phenomenon called skirt shape (hereinafter referred to as skirting) in which a skirt region of upper layer of conductive film is extremely lengthened has been caused.

In the FIG. 8A, a cross sectional SEM (scanning electron microscope) image of twenty thousand magnification showing two layered conductive film in which skirting is noted in the lower layer is illustrated. Reference numeral 7200 denotes a resist used as a mask, 7201 denotes an upper layer of conductive film, and 7202 denotes a lower layer of conductive film.

In addition, the conductive film shown in FIG. 8A is formed of a TaN film with a thickness of 30 nm as a lower layer and a W film with a thickness of 370 nm as an upper layer. And the conductive film having two layers of 7201 and 7202 was formed by two times of etching. ICP etching was used in both times as etching.

Cl₂, CF₄, and O₂ are introduced in the flow rate of 25/25/10 sccm, and the total pressure is set to 1.5 Pa for the first etching process. Further, high frequency (hereinafter referred to as RF) power (13.56 MHz) of 500 W is applied to the coil shape electrode and RF power (13.56 MHz) of 150 W is applied to the side of the substrate (sample stage). Then an etching gas is changed to the Cl₂, and CF₄, the flow rate thereof is set to as 30/30 sccm respectively at a total pressure of 1.5 Pa. Moreover, RF power (13.56 MHz) of 500 W is applied to the coil shape electrode and RF power (13.56 MHz) of 10 W is applied to the side of the substrate.

As the second etching processing, Cl₂, SF₆, and O₂ are introduced in the flow rate of 25/25/10 sccm at a total pressure of 1.3 Pa. Further, RF power (13.56 MHz) of 700 W is applied to the coil shape electrode and RF power (13.56 MHz) of 10 W is applied to the side of the substrate (sample stage).

A cross sectional SEM image of the forty thousand magnification at the end of the gate electrode is shown in FIG. 8B in order to observe the upper layer 7201 of gate electrode and the lower layer 7202 of gate electrode shown in the SEM image of FIG. 8A in detail. In FIG. 8B, it is noted that 7203 that is one part of the upper layer of 7201 of the gate electrode is left without being etched, and the lower layer 7202 of the gate electrode is covered with the portion 7203 left as skirting. Therefore, impurities are not sufficiently doped into a Lov region which is to be formed under the lower layer 7202 of the gate electrode, and a width Wov in the channel length direction of the region which functions as the Lov region in reality is shortened.

A structure in cases where skirting is caused in a TFT shown in FIG. 7A is illustrated in FIG. 7B. Reference numeral 6007 that is a skirting portion of the upper layer of the gate electrode 6003a is remained without being etched. As a result, the area of the region where the upper layer of the gate electrode 6003a is overlapped with and lower layer of the gate electrode 6003b is increased, and the width Wov of the Lov region is shortened by just that much.

Also, when the width Wov of the Lov region is shortened, hot carrier effect can not be suppressed since relaxation of drain electric field becomes insufficient, and the reliability of a TFT can not be attained.

### SUMMARY OF THE INVENTION

Considering the above-described problems, it is an object of the present invention to provide a method for cleaning plasma etching apparatus, a method for plasma etching, and a method for manufacturing a semiconductor device using the method for plasma etching each of which can suppress the phenomenon called the skirting, and reduce the dispersion in reliability in a TFT among lots.

From the results of a comparative study of manufacturing conditions among lots in which development of a skirting is seen, and lots in which skirting does not occur, the applicants of the present invention discovered that skirting occurs when anisotropic etching is performed on a conductive film having two layers after performing etching using an etching gas containing BCl₃ in the same etching apparatus.

Results of observing the presence or absence of skirting when two layer conductive films on quartz substrates are anisotropically etched, after first exposing dummy substrates to plasma as a preprocessing using different kinds of etching gases, are shown in TABLE 1. Note that TaN was used in a lower layer of the conductive film, and W was used in an upper layer of the conductive film. SF₆ was used as an etching gas. Etching was then performed using an inductively coupled plasma (ICP) etching apparatus under conditions where the lower layer was anisotropically etched at a slower speed than the upper layer. Further, determination of the presence or absence of skirting was made by observing the shape using SEM.

TABLE 1

| | | TREATMENT TIME FOR | PRESENCE |
|---|---|---|---|
| | ETCHING | DAMMY QUARTZ | OR |
| TEST | GAS USED | SUBSTRATE × | ABSENCE |
| PIECE | IN PRE- | NUMBER OF | OF |
| No. | PROCESSING | TREATED SUBSTRATE | SKIRTING |
| 1 | Cl₂ | 2 min × 10 SLICES | ABSENCE |
| 2 | BCl₃ + Cl₂ | 2 min × 10 SLICES | PRESENCE |
| 3 | Cl₂ | 2 min × 10 SLICES | ABSENCE |
| 4 | BCl₃ + Cl₂ | 3 min × 14 SLICES | PRESENCE |
| 5 | O₂ + CF₄ | 4 min × 3 SLICES | PRESENCE |
| 6 | O₂ + CF₄ | 4 min × 5 SLICES | PRESENCE |
| 7 | Cl₂ | 2 min × 5 SLICES | PRESENCE |
| | | | BUT |
| | | | SLIGHTLY |
| | | | IMPROVED |

Further, SEM images of substrates that have undergone the processing of TABLE 1 are shown in FIGS. 1A to 1G. Dashed lines in FIGS. 1A to 1G. show boundary lines between the lower layer and the upper layer of the conductive films. This shows that the development of skirting becomes more prominent with increasing distance from resist. Note that FIG. 1A corresponds to a test piece No. 1, FIG. 1B corresponds to a test piece No. 2, FIG. 1C corresponds to a test piece No. 3, FIG. 1D corresponds to a test piece No. 4, FIG. 1E corresponds to a test piece No. 5, FIG. 1F corresponds to a test piece No. 6, and FIG. 1G corresponds to a test piece No. 7.

From the results shown in TABLE 1 and in FIGS. 1A to 1G, it is understood that BCl₃ is a cause of skirting.

BCl₃ is used as an etching gas for Al and Ti. It is mainly used in etching for wirings made of Al that provide electrical connections to TFTs. The applicants of the invention conjectured that BOₓ compounds, such as B₂O₃, adhering to a quartz surface, which is employed within a chamber of the etching apparatus, when BCl₃ is used as an etching gas, will interfere with plasma reactions by exciting or dissociating an etching gas used during subsequent processes.

Therefore, the inventors of the present invention considered that, the plasma density may be kept constant by exciting plasma using a gas capable of etching quartz, for example, Cl₂ or a mixed gas of Cl₂ and a fluorine-based gas such as CF₄ after using an etching gas such as BCl₃, with which BOₓ adheres to the quartz surface. The BOₓ adhering to the quartz surface within the chamber is thus removed (that is, cleaning is performed), and skirting that would occur in the next etching process may thus be able to be suppressed.

Note that the above-mentioned cleaning method of the present invention may be performed after using the etching gas with which BOₓ adheres to the quartz surface by exciting the plasma. The etching gas is not limited to BCl₃.

Further, a gas used in cleaning (cleaning gas) is not limited to Cl₂ or to a mixed gas of Cl₂ and CF₄. In addition to CF₄, SF₆, NF₃, and the like can be used as other fluorine-based gases. However, gases such as CHF₃, which can etch quartz but leaves new residue such as CFₓ on the quartz surface, are not preferably used as the cleaning gas. Further, the cleaning gases described above may also be used when O₂ is added to the cleaning gas. For example, it is possible to use a mixed gas of Cl₂, SF₆, and O₂ as the cleaning gas.

Further, there is a tendency for portions of a gate insulating film that are exposed to the plasma to also be etched during etching the conductive film. The amount that the film thickness of the gate insulating film reductions differs according to lot, along with the occurrence of skirting. However, by removing the BOₓ using the method described above, the plasma density when etching can be kept constant, regardless of kind of etching gas is used in preprocessing. The reduction in the film thickness of the gate insulating film can therefore also be kept constant.

The reductions in the film thickness of gate insulating films due to etching are shown in FIG. 2 by lot. Further, an x-Rs control chart is also shown. The horizontal axis shows the lot number. The reductions in the film thickness are shown above the horizontal axis of the graph, while Rs (moving range) is shown below the horizontal axis.

Measurements were made on test pieces obtained by laminating a 53 nm thick amorphous silicon film, a 100 nm thick silicon nitride oxide film, a first conductive film of TaN, and a second conductive film of W in sequence, and by performing anisotropic etching on the first conductive film of TaN and the second conductive film of W. Measurements were also made on test pieces obtained by performing isotropic etching on the above test pieces. The average value of the film thickness of the gate insulating film was obtained for each test piece at 49 points within the surface of the substrate by using an ellipsometer. The difference between the average values of two test pieces was plotted as the amount of the reduction in the film thickness.

Anisotropic etching was performed by ICP etching. Specifically, ICP etching was performed for 25 seconds at a pressure of 1.3 Pa by using an etching gas in which Cl₂, SF₆, and O₂ were mixed at flow rates of 12/24/24 sccm, respectively. Further, a 700 W RF power (13.56 MHz) was applied to a coil shape electrode, and a 10 W RF power (13.56 MHz) was applied to the substrate (test piece stage).

Note that none of the lot numbers to the left of Lot 26 was employed the method for cleaning an etching apparatus of the present invention (hereinafter referred to as the cleaning method of the present invention), while Lot 26 and those lot numbers to the right of Lot 26 all were employed the cleaning method of the present invention. Note also that cleaning was performed using Cl₂ for Lot 26 through Lot 35, with a processing time of approximately 10 minutes. From Lot 36 to Lot 47, a mixed gas of Cl₂ and CF₄ was used with a processing time of approximately 6 minutes, and then, the cleaning gas was changed to Cl₂ and processing was performed for approximately 6 minutes.

Further, an upper control limit (UCL), a lower control limit (LCL), and a center line (CL) that were found by employing a three sigma method on the amount of the reduction in film thickness are shown in FIG. 2 for each of the lots where cleaning was performed. In addition, an upper control limit (UCL′) and a centerline (CL′) found by employing a three sigma method on Rs are also shown in FIG. 2 for the lots in which cleaning was performed.

The CL value is the average value of the amount of the reduction in the film thickness. The UCL value can be calculated by multiplying an average value of Rs by a factor of 2.66, and adding a resultant value to the CL value. A LCL value can be obtained by multiplying the average value of Rs by a factor of 2.66, and subtracting the result from the CL value. Further, the CL′ value is an average value of Rs. A UCL′ value can be obtained by multiplying the CL′ value by a factor of 3.27.

Specifically, the UCL value of the reduction in the amount of the film thickness was found to be 14.805 nm, the LCL value was found to be 7.835 nm, and the UCL′ value was found to be 4.284 nm in the lots where cleaning was performed.

Skirting could not be seen in the lots where cleaning was performed, and the reductions in the film thickness in these lots were kept within a range bounded by the control limits described above.

On the other hand, among the lots where cleaning was not performed, skirting was seen in Lot 01, Lot 04, Lot 11, Lot 14, Lot 17, Lot 19, Lot 22, and Lot 23. These lots all deviated from the range bounded by the control limits described above. Of the lots where cleaning was not performed, the lots where skirting was not seen were all kept within the range bounded by the control limits described above, with the exception of Lot 09.

From these results, it is understood that the occurrence (development) of skirting and the occurrence of dispersion in the film thickness of the gate insulating film are not phenomena that occur separately, but are phenomena that both come from the same cause.

From FIG. 2, it can be understood that the amount of the reduction in the film thickness of the gate insulating films is random in the lots where the cleaning method of the present invention was not used. On the other hand, it can be understood that the amount of the reduction in the film thickness can be maintained relatively uniform in the lots where the cleaning method of the present invention was performed. This can also be understood from the fact that the average value of Rs, which shows fluctuation in the amount of the reduction in the film thickness between lots, is 2.65 nm for all of the lots, but only 1.31 nm for the lots where cleaning was performed.

The average amount of the reduction in the film thickness of the gate insulating films was 10.743 nm over all of the lots, but was 11.32 nm for the lots where cleaning was performed. It can thus be understood that performing cleaning tends to make the gate insulating films easier to be etched.

It is thought that this is because deposits that inhibit reaction with the plasma of the etching gas are removed from the quartz within the chamber by performing cleaning, and therefore the plasma density can be maintained relatively constant. In other words, it is difficult to maintain the plasma density as constant during anisotropic etching when cleaning is not performed, because the kinds of etching gases used for the preprocessing in each of the lots were diverse. Therefore it can be considered that the film thickness of the gate insulating films becomes random.

Note that the fluctuation in the film thickness was smaller for the lots where cleaning was performed by using a mixed gas of Cl₂ and CF₄ than the lots where cleaning was performed by using only Cl₂, and it can be understood that the adhered residues were very effectively removed.

Dispersion in the film thickness of the gate insulating film can therefore be suppressed by using the cleaning method of the present invention. When doping impurities into a semiconductor film through a gate insulating film, thus forming a source/drain region, the concentration of the impurities in the source/drain region depends on the film thickness of the gate insulating film. By suppressing dispersion in the film thickness of the gate insulating film, dispersion in the TFT characteristics among lots, specifically dispersion in the impurity concentration of the source/drain region, can be controlled.

Further, by using the cleaning method of the present invention, the phenomenon referred to as skirting that occurs in anisotropic etching can be prevented. The hot carrier effect, where the width of a Lov region becomes shorter, can therefore be prevented from occurring. TFT reliability can be increased, and moreover, dispersion in the reliability among lots can be suppressed.

The present invention is not only effective in cleaning the BOₓ by a fluorine-based gas, but also effective in improving the stability of an etching rate and an atmosphere within a chamber by adopting an appropriate etching gas for cleaning residues adhering to an inside of the chamber.

### BRIEF DESCRIPTION OF THE DRAWINGS

FIGS. 1A to 1G are SEM images of substrates that have undergone the processing of TABLE 1;

FIG. 2 is a diagram showing the amount of reduction in the film thickness of gate insulating films due to etching by lot and an x-Rs control chart;

FIGS. 3A to 3D are diagrams showing a method for manufacturing a semiconductor device using a cleaning method of the present invention;

FIGS. 4A and 4B are enlarged views of the vicinity of the LDD region 7012 in the TFT shown in FIG. 3D;

FIG. 5 is a SEM image in section of two layered conductive film in which skirting cannot be seen;

FIG. 6 is a diagram showing a structure of an ICP apparatus;

FIGS. 7A and 7B are diagrams showing a structure of a TFT provided with two layered gate electrode which is different in width in a channel length direction; and

FIGS. 8A and 8B are SEM images of two layered conductive film in which skirting can be seen in the lower layer.

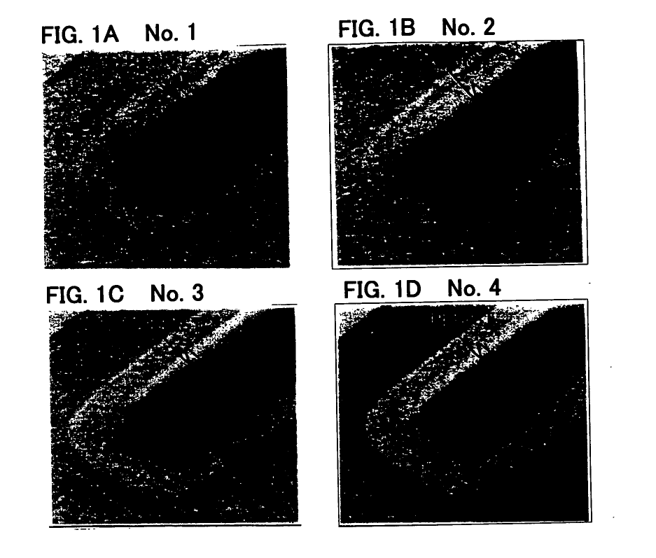

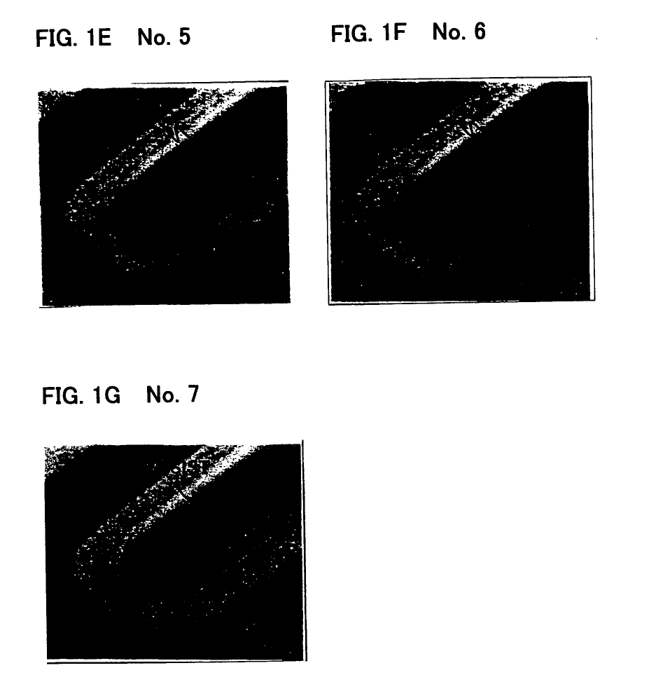

### DETAILED DESCRIPTION OF THE PREFERRED EMBODIMENTS

A method for manufacturing a semiconductor device by using the cleaning method of the present invention is explained next.

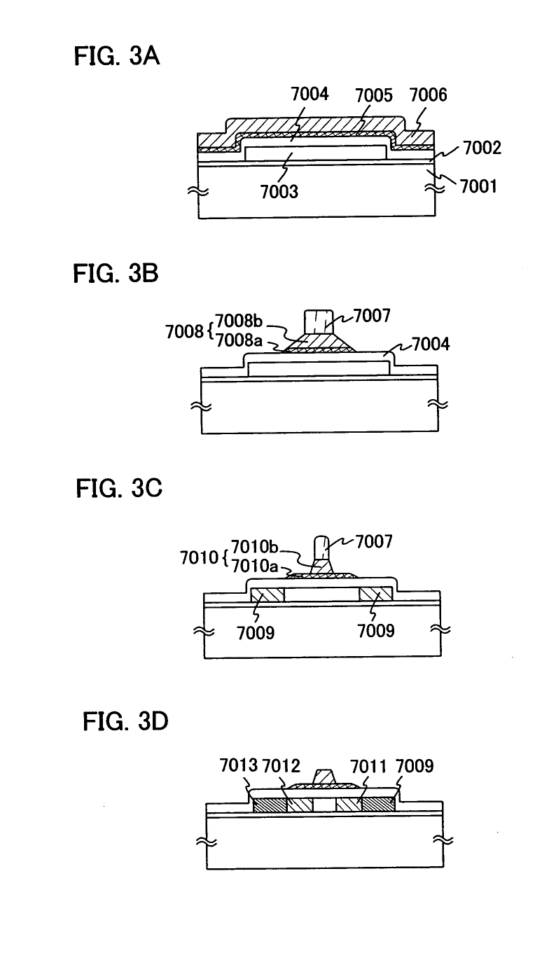

As shown in FIG. 3A, a base film 7002 is formed first on a substrate 7001. Glass substrates such as barium borosilicate glass and aluminum borosilicate glass, quartz substrates, SUS substrates, and the like can be used for the substrate 7001. Further, although substrates made from a synthetic resin having flexibility, such as plastic, tend to generally have a lower heat resistance temperature compared to the substrates described above, it is possible to use the synthetic resin substrates as the substrate 7001 as long as they are able to withstand the process temperatures in the manufacturing processes.

The base film 7002 is formed in order to prevent alkaline metals and alkaline earth metals contained within the substrate 7001, such as Na, from diffusing within a semiconductor film and exerting an adverse influence to semiconductor device characteristics. The base film 7002 is therefore formed by using an insulating film capable of suppressing the diffusion of alkaline metals and alkaline earth metals to the semiconductor film, such as a silicon oxide film, a silicon nitride film, or a silicon oxynitride film. In this embodiment mode, the base film 7002 is formed from a silicon nitride oxide film deposited by using plasma CVD and having a film thickness of 10 to 400 nm (preferably from 50 to 300 nm).

Note that the base film 7002 may be a single layer, or may be a laminate of a plurality of insulating films. Further, although it is effective to form the base film in order to prevent impurity diffusion when using a substrate that contains a certain amount of alkaline metals or alkaline earth metals, such as a glass substrate, or an SUS substrate. However, the base film need not be formed when using a quartz substrate or the like, with which impurity diffusion does not become a problem.

An island shape semiconductor film 7003 is formed next on the base film 7002. The film thickness of the island shape semiconductor film 7003 is set from 25 to 100 nm (preferably from 30 to 60 nm). Note that the island shape semiconductor film 7003 may be an amorphous semiconductor, a microcrystalline semiconductor (semi-amorphous semiconductor), or a polycrystalline semiconductor. Further, not only can the semiconductor use silicon, it can also use silicon germanium. It is preferable that the germanium concentration be on the order of 0.01 to 4.5 atomic % when silicon germanium is used.

When a polycrystalline semiconductor is used, an amorphous semiconductor is formed first. The amorphous semiconductor is then crystallized by using a known method of crystallizing an amorphous semiconductor. A method for performing crystallization by heating using a heater, a method for performing crystallization by laser light irradiation, a method for performing crystallization by using a catalyst metal, a method for performing crystallization by using infrared light, and the like can be given as known methods of crystallization.

When crystallizing the amorphous semiconductor film by using laser light, for example, a pulsed laser or a continuous wave excimer laser, YAG laser, YVO₄ laser, or the like is used. For example, when a YAG laser is used, a wavelength of a second harmonic, which tends to easily be absorbed by the semiconductor film, is employed. The oscillating frequency is set from 30 to 300 kHz, the energy density is set from 300 to 600 mJ/cm² (typically from 350 to 500 mJ/cm²), and the scanning speed may be set so that several irradiation shots can be emitted at an arbitrary point.

A gate insulating film 7004 is formed next covering the island shape semiconductor film 7003. The film thickness of the gate insulating film is reduced on the order of 10 to 20 nm during later dry etching in order to form a gate electrode, and therefore it is preferable that the film thickness of the gate insulating film be set after considering the reduction. Specifically, the gate insulating film is formed to have a thickness on the order of 40 to 150 nm (preferably from 60 to 120 nm).

Silicon oxide, silicon nitride, silicon nitride oxide, and the like can be used as a gate insulating film, for example. Further, plasma CVD, sputtering, and the like can be used as the film formation method. For example, when forming the gate insulating film by a silicon oxide film deposited by using plasma CVD, film formation may be performed by using a mixed gas of tetraethyl orthosilicate (TEOS) and O₂, at a reaction pressure to 40 Pa, a substrate temperature of 300 to 400° C., and a RF power density (13.56 MHz) of 0.5 to 0.8 W/cm².

Further, aluminum nitride can also be used as the gate insulating film. The thermal conductivity coefficient of aluminum nitride is relatively high, and TFT heat generated can be dissipated efficiently. Further, a gate insulating film in which aluminum nitride is laminated after first forming silicon oxide, silicon nitride oxide, or the like, which contain no aluminum, may also be used.

Conductive films are formed next on the gate insulating film 7004. A first conductive film 7005 comprising TaN is formed at a thickness of 20 to 100 nm, and a second conductive film 7006 comprising W is formed at a thickness of 100 to 400 nm.

Specifically, a film of TaN that is used in the first conductive film 7005 is formed at a film formation speed of approximately 40 nm/min. This is achieved by using a Ta target having a purity of 99.99%, with an internal chamber temperature set to room temperature, a gas flow rate for Ar set to 50 ml/min, a gas flow rate for N₂ set to 10 ml/min, an internal chamber pressure set to 0.6 Pa, and a film formation electric power set to 1 kW. Further, a film of W that is used in the second conductive film 7006 is formed at a film formation speed of approximately 390 nm/min. This is achieved by using a W target having a purity of 99.99%, with an internal chamber temperature set to 230° C., a gas flow rate for Ar set to 100 ml/min, an internal chamber pressure set to 1.5 Pa, and a film formation electric power set to 6 kW.

A mask 7007 is formed next, and etching is performed on the first conductive film 7005 and the second conductive film 7006 as shown in FIG. 3B (first etching process). Etching is performed in this embodiment mode by using inductively coupled plasma (ICP) etching. A mixed gas of Cl₂, CF₄, and O₂ is used as an etching gas, and pressure of the etching gas within the chamber is set to 1.0 Pa. A 13.56 MHz RF power of 500 W is applied to a coil shape electrode, generating plasma. Further, a 13.56 MHz RF power of 150 W is applied to a stage (lower portion electrode) on which the substrate is placed, thus applying a self-bias voltage to the substrate. The etching gas is then changed to a mixture of Cl₂ and CF₄, and the total pressure is set to 1.0 Pa. Further, an RF power (13.56 MHz) of 500 W is applied to the coil shape electrode, and an RF power (13.56 MHz) of 20 W is applied to the substrate side (test piece stage).

The etching rate of TaN, of which the first conductive film 7005 is formed, and the etching rate of W, of which the second conductive film 7006 is formed, become nearly equal when CF₄ and Cl₂ are used as the etching gas, and both can undergo etching on the same order.

A first shape conductive film 7008 structured by a lower layer 7008a and an upper layer 7008b are thus formed by the first etching process. Note that sidewalls of the lower layer 7008a and the upper layer 7008b take on a slight tapered shape in the first etching process. Further, when etching is performed so that no conductive film residue remains, a surface of the gate insulating film 7004 that is not covered by the first shape conductive film 7008 may undergo etching on the order of 5 to 10 nm.

A second etching process is performed next in an ICP etching apparatus, and the first shape conductive film 7008 is etched as shown in FIG. 3C. And, cleaning of the inside of the chamber in the ICP etching apparatus is performed before the second etching in the present invention.

For example, a dummy substrate of quartz or the like is set on the stage in this embodiment mode, and the inside of the chamber is cleaned. Cl₂, or a mixed gas of Cl₂ and CF₄ is used as a cleaning gas. For example, the flow rate is set to 80 sccm when Cl₂ is used, and the flow rates of each gas are set to 40 sccm when Cl₂ and CF₄ are used.

The pressure of the cleaning gas within the chamber is set from 0.5 to 3 Pa (preferably from 1.0 to 2 Pa), an RF power is applied to the coil shape electrode, generating plasma, and cleaning is performed for a period on the order of 120 seconds. In this embodiment mode, a 13.56 MHz RF power of 450 W is applied to the coil shape electrode, thus generating plasma. Further, a 13.56 MHz RF power of 100 W is applied to the stage (lower portion electrode), thus applying a self-bias voltage to the dummy substrate.

The amount of cleaning time, and the RF power applied to each electrode, depend on the amount of BOₓ adhering to quartz within the chamber, and therefore it is preferable for an operator to set suitable values.

The first conductive film 7008 is then etched (second etching process) as shown in FIG. 3C using the mask 7007. A surface of the mask 7007 has already been etched by the first etching process, and the width of the mask 7007 has become smaller. The second etching process is also performed by using ICP etching, the same method as used by the first etching process. A mixed gas of SF₆, Cl₂, and O₂ is used as the etching gas, and the pressure of the etching gas within the chamber is set to 1.3 Pa. A 13.56 MHz RF power of 700 W is then applied to the coil shape electrode, generating plasma. Further, a 13.56 MHz RF power of 10 W is introduced to the stage (lower portion electrode), thus applying a self-bias voltage to the substrate.

An etching rate of W increases and an etching rate of TaN, which forms the lower layer 7008b of the first shape conductive film 7008, is greatly reduced when O₂ is added to the mixed gas of SF₆ and Cl₂. Higher selectivity ratio (ratio of an etching rate of W to an etching rate of TaN) can therefore be achieved.

A second shape conductive film 7010 (a lower layer 7010a and an upper layer 7010b) is formed by the second etching process. A width of the upper layer 7010b of the gate electrode 7010 in the channel length direction becomes shorter than the width of the lower layer 7008b. The second shape conductive film 7010 functions as a gate electrode. Further, a surface of the gate insulating film 7004 that is not covered by the gate electrode 7010 undergoes etching on the order of 5 to 10 nm by the second etching process.

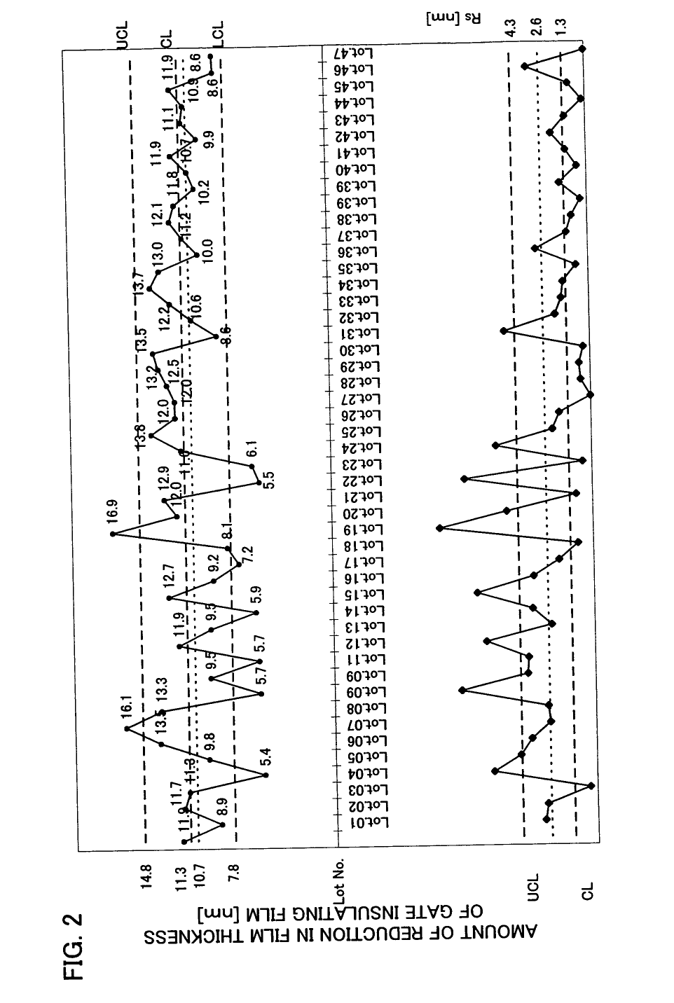

It is not necessary to implement the cleaning method of the present invention for all lots. The cleaning method of the present invention need only be performed for processes occurring after using an etching gas with which BOₓ adheres to the quartz within the chamber, such as BCl₃. However, as can be understood from FIG. 2, the Rs value can be kept small, and dispersion in the film thickness of the gate insulating film can be controlled, by always implementing the cleaning process of the present invention before etching processes. The cleaning method of the present invention is therefore implemented before the second etching process in this embodiment mode, and may also be implemented before the first etching process.

As shown in FIG. 3C, impurities that impart n-type conductivity are next added to the island shape semiconductor film 7003 using the gate electrode 7010 as a mask (first doping process). Doping is performed by ion implantation. Doping is performed with a dose amount of 1×10¹³ to 5×10¹⁴ atoms/cm², and an acceleration voltage of 40 to 80 kV. Group 5 atoms such as P, As, and Sb, and group 6 elements such as S, Te, and Se, which all function as donors, may be used as the impurity device that imparts n-type conductivity. P is used in this embodiment mode.

Note that although a process of manufacturing an n-channel TFT is shown in this embodiment mode, group 3 elements such as B, Al, Ga, and In, and group 2 elements such as Zn, which are all acceptors, may be added when manufacturing a p-channel TFT.

A first impurity region 7009 is formed in a self-aligning manner by the first doping process. An impurity element that imparts n-type conductivity is added to the first impurity region 7009 at a concentration range of 1×10¹⁸ to 1×10²⁰ atoms/cm³.

A second doping process is performed next as shown in FIG. 3D, using the upper layer 7010b of the gate electrode 7010 as a mask. The acceleration voltage used in the second doping process is set higher than that used in the first doping process to make the impurities pass through the lower layer 7010a of the gate electrode 7010. The second doping process forms an LDD region, and therefore the dose amount of the n-type impurities is set lower than that used in the first doping process. Specifically, the acceleration voltage is set from 60 to 120 kV, and the dose amount is set from 1×10¹³ to 1×10¹⁵ atoms/cm².

A third doping process is performed next at an acceleration voltage set lower than that used in the second doping process, and the state shown in FIG. 3D is obtained. The acceleration voltage is set from 50 to 100 kV, and the dose amount is set from 1×10¹⁵ to 1×10¹⁷ atoms/cm² in the third doping process. A second impurity region 7012 that overlaps with the lower layer 7010a of the gate electrode 7010, and a third impurity region 7013 that is formed by adding more of the impurities to the first impurity region 7009, are formed by the second doping process and the third doping process. The n-type conductivity imparting impurities are added to the second impurity region 7012 at a concentration range of 1×10¹⁸ to 5×10¹⁹ atoms/cm³, and the n-type conductivity imparting impurities are added to the third impurity region 7013 at a concentration range of 1×10¹⁹ to 5×10²¹ atoms/cm³.

The second impurity region 7012 is formed in an inner side of the third impurity region 7013. The second impurity region 7012 functions as an LDD region, and the third impurity region functions as a source or a drain region.

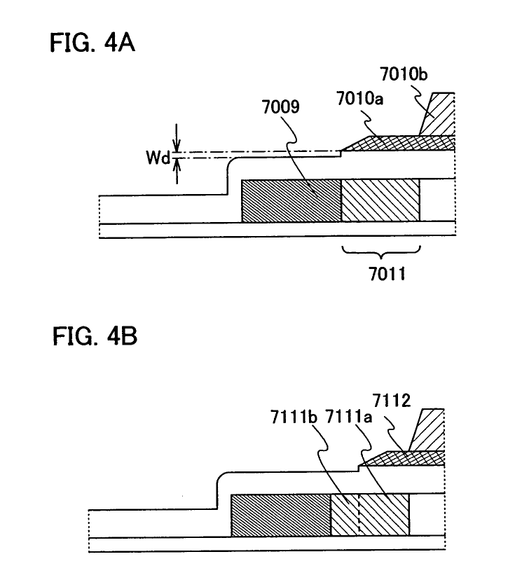

An enlarged view is shown in FIG. 4A of the vicinity of the LDD region 7012 in the TFT shown in FIG. 3D. The LDD region 7012 overlaps with the lower layer 7010a of the gate electrode 7010, thus functioning as a Lov region, as shown in FIG. 4A.

It is of course also possible to form a low concentration impurity region and a high concentration impurity region by making the second doping process and the third doping process into one doping process performed at a suitable acceleration voltage.

When the second doping process is complete, heat treatment is performed in order to activate the impurity elements added to the island shape semiconductor film. This process can be performed by thermal annealing using an annealing furnace, by laser annealing, or by rapid thermal annealing (RTA). For example, when performing activation by thermal annealing, it is performed at a temperature of 400 to 700° C. (preferably from 500 to 600° C.) under a nitrogen atmosphere containing an oxygen at a concentration of equal to or less than 1 ppm, preferably equal to or less than 0.1 ppm.

In addition, heat treatment is performed at 300 to 450° C. for 1 to 12 hours within an atmosphere containing 3 to 100% hydrogen, thus performing hydrogenation of the island shape semiconductor film. This process is one of terminating dangling bonds in the semiconductor layer by thermally excited hydrogen. Plasma hydrogenation (using hydrogen excited by plasma) may also be performed as another means of hydrogenation.

Further, the activation process may also be performed after forming an insulating film containing silicon, such as silicon oxide, silicon nitride, or silicon oxynitride, having a thickness on the order of 100 to 200 nm.

The TFT can be formed by the series of processes described above. Note that the surface of the gate insulating film 7004 not covered with the gate electrode 7010 is etched by an amount on the order of 10 to 20 nm by the first and the second etching processes. By performing the cleaning method of the present invention, dispersion in an etching thickness Wd of the gate insulating film by lot can be suppressed, and dispersion in the TFT characteristics can also be suppressed.

Further, the entire LDD region 7012 overlaps with the lower layer 7010a of the gate electrode 7010 in this embodiment mode, and therefore the LDD region 7012 functions as a Lov region. The present invention is not limited to this structure, however. For example, by performing a doping process between the first etching process and the second etching process, thus forming a source or a drain region, and moreover, by etching the lower layer of the gate electrode to have a shorter channel length in the channel length direction by the second etching process, both a Lov region 7111a that overlaps with the lower layer 7112 of the gate electrode, and a Loff region 7111b that does not overlap with the lower layer 7112 of the gate electrode can be formed.

Note that although TaN is used as the first conductive film, and W is used as the second conductive film in this embodiment mode, the gate electrode materials are not limited to these. An element selected from the group consisting of Ta, W, Ti, Mo, Al, and Cu, and alloys and chemical compounds having one of these elements as its main constituent may be used in forming the gate electrode. For example, a gate electrode in which Ta is used in a first layer and W is used in a second layer, a gate electrode in which TaN is used in the first layer and Al is used in the second layer, and a gate electrode in which TaN is used in the first layer and Cu is used in the second layer can all be considered. Further, a gate electrode in which an Ag—Pd—Cu alloy is used in the first layer or the second layer may also be used.

Further, the conductive film is not limited to having two layers. A single layer conductive film, and conductive films having three or more layers may also be used. For example, a three layer structure in which W, an alloy of Al and Si (Al—Si), and TiN are laminated in sequence may be used. Further, tungsten nitride may also be used as a substitute for W, an alloy of Al and Ti (Al—Ti) may also be used as a substitute for the alloy of Al and Si (Al—Si), and Ti may also be used as a substitute for TiN. However, when forming a plurality of conductive films, materials that have mutual etching selectivity ratio with each other are used in order to have difference in the width of the gate electrode in the channel length direction in each of the conductive films.

Note that it is very important to select optimal etching gases according to the conductive film materials.

Note that the plasma etching process described above is not limited to an ICP etching method. For example, an electron cyclotron resonance (ECR) etching method, an RIE etching method, a helicon wave etching method, a helical resonance etching method, a pulse modulation etching method, and other plasma etching methods may also be used.

Note that, although the RF power is applied in order to generate plasma in the specification, it is also possible to apply, for example, ultra high frequency (UHF) power.

The phenomenon referred to as skirting can be prevented from occurring in anisotropic etching by using the cleaning method of the present invention. The hot carrier effect, where the width of a Lov region becomes shorter, can therefore be prevented from occurring. TFT reliability can be increased, and moreover, dispersion in the reliability among lots can be suppressed.

Note that the present invention can be used in a method for manufacturing a semiconductor device, typically an integrated circuit or a semiconductor display apparatus. Specifically, the present invention can be used in manufacturing liquid crystal display device, light emitting device provided with a light emitting element, typically an organic light emitting device, in each pixel, digital micromirror apparatuss (DMDs), plasma display panels (PDPs), field emission displays (FEDs), and the like.

[Embodiments]

Embodiments of the present invention are explained below.

Embodiment 1

A cross sectional SEM image of a two layered conductive film where it has been determined that skirting has not occurred is shown in this embodiment.

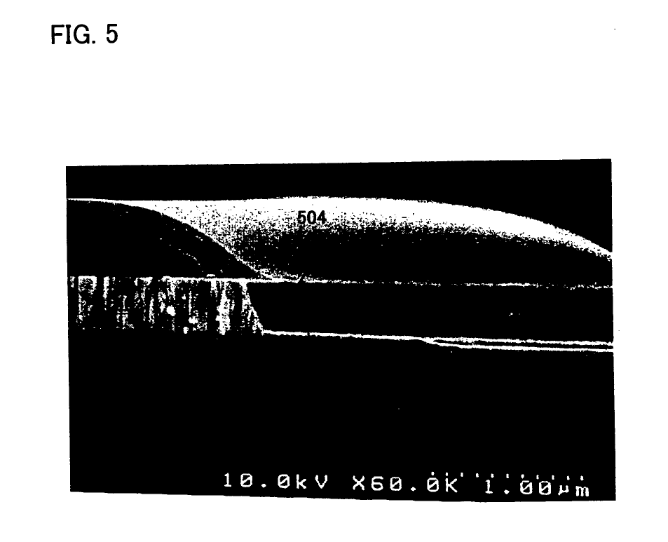

Note that a conductive film shown in FIG. 5 has a lower layer 501 that is formed of 30 nm of TaN, and an upper layer 502 that is formed of 70 nm of W. An etching process has been implemented two times to the two conductive film layers 501 and 502. Both of the etching processes used were ICP etching. In a first etching process, Cl₂ and CF₄ were supplied at flow rates of 30 sccm and 30 sccm, respectively, and the total pressure was set to 1.5 Pa. Further, a 500 W RF power (13.56 MHz) was applied to a coil shape electrode, and a 150 W RF power (13.56 MHz) was applied to a substrate side (test piece stage). Further, in a second etching process, Cl₂, SF₆, and O₂ were supplied at rate of 12/24/24 sccm, respectively, and the total pressure was set to 1.3 Pa. Furthermore, a 700 W RF power (13.56 MHz) was applied to the coil shape electrode, and a 10 W RF power (13.56 MHz) was applied to the substrate side (test piece stage).

Note that reference numeral 503 corresponds to a mask formed of resist.

In the SEM image shown in FIG. 5, skirting cannot be seen in a portion of a hem of the upper layer 502 surrounded by a dashed line 504.

Embodiment 2

In this embodiment, a structure of ICP etching apparatus and about a part of the chamber in which quartz is used are described.

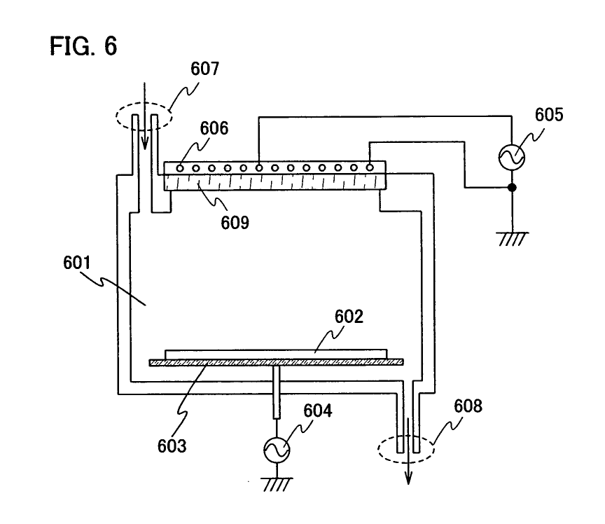

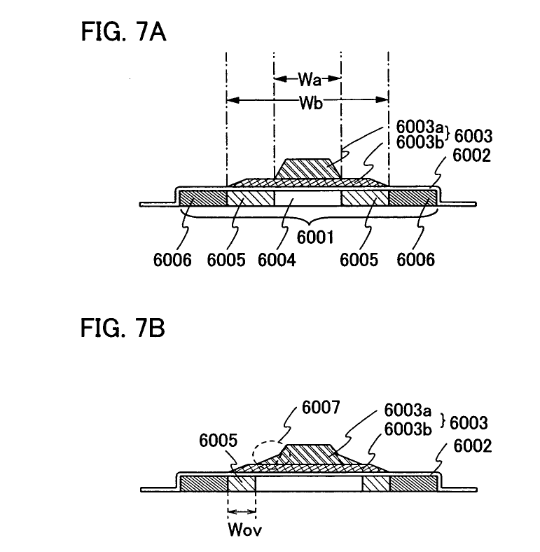

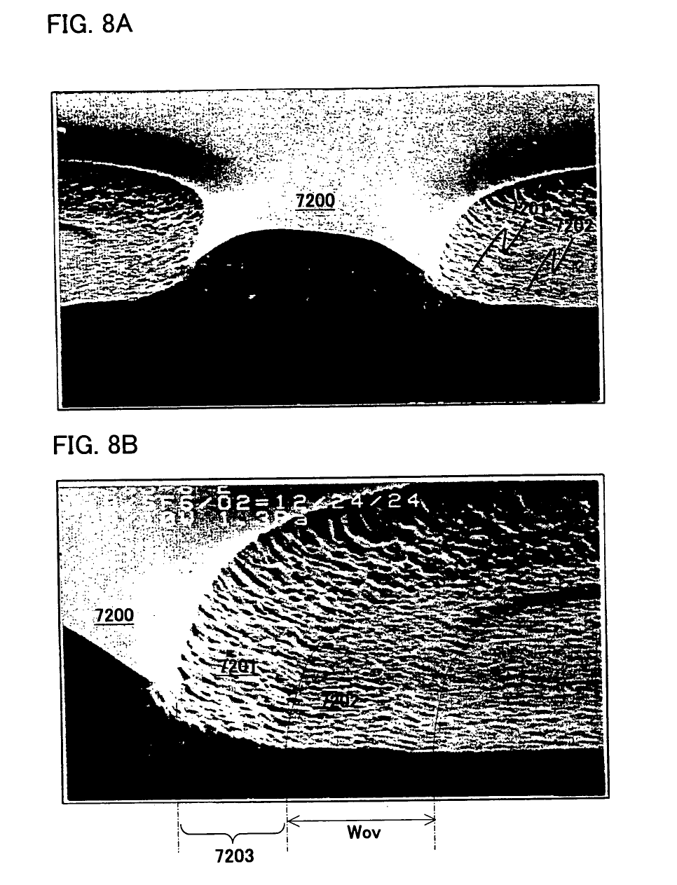

In FIG. 6, a structure of ICP etching apparatus with reference to the present embodiment is illustrated. Reference numeral 601 is a chamber (reaction chamber) which is provided with a stage 603 where a substrate 602 as treated object is mounted thereon.

Furthermore, a gas supply port 607 for supplying etching gas or cleaning gas into the chamber 601 and an exhaust port 608 for exhausting the air inside the chamber 601 are provided in the chamber 601. A supply means for etching gas and cleaning gas is connected to the gas supply port 607 and an exhaust means for vacuum pump is connected to the exhaust port 608.

Reference numeral 606 indicates a coil shape electrode (antenna) and 609 indicates a quartz substrate. Dielectric magnetic field is generated by supplying electric power from RF power source 605 to an electrode 606 and is applied into the chamber through the quartz substrate. Electrons are accelerated and plasma is generated according to the dielectric magnetic field.

Moreover, the stage 603 is to be supplied with RF power from a RF power source 604, and functions as a bottom electrode. By high frequency power that is supplied from the RF power source 604, self-bias voltage can be applied to the substrate 602.

The quartz substrate 609 is exposed to the inside of the chamber in the ICP etching apparatus shown in FIG. 6. And BOₓ is attached to the surface exposed to the inside of the chamber when BCl₃ or the like is used as an etching gas. According to the cleaning method of the present invention, the BOₓ attached to the quartz substrate can be removed and decline in plasma density inside the chamber due to the BOₓ can be suppressed.

According to the cleaning method of the present invention, residues such as BOₓ in plasma etching apparatus can be removed. Further, phenomenon called skirting can be prevented from occurring in anisotropic etching by using the cleaning method of the present invention. In addition, shortening of width of a Lov region due to skirting, and the occurrence of hot carrier effect can be suppressed, consequently, the reliability of a TFT can be improved and the dispersion in reliability in a TFT characteristic among lots can be reduced. Moreover, the dispersion in film thickness of gate insulating film can be controlled, and therefore, the dispersion in TFT characteristic among lots, specifically, the dispersion in impurity concentration can be reduced.

What is claimed is:

1. A method for cleaning a plasma etching apparatus comprising the steps of:
filling a chamber with Cl₂ or a mixed gas of Cl₂ and a fluorine-based gas wherein BOₓ is adhered to an inside of the chamber as a residue; and
generating plasma from the Cl₂ or the mixed gas of Cl₂ and the fluorine-based gas to remove the BOₓ.

2. A method for cleaning a plasma etching apparatus according to claim 1, wherein a method selected from the group consisting of an RIE etching method, an ICP etching method, an ECR etching method, a helicon wave etching method, a helical resonance etching method and a pulse modulation etching method is adopted in the plasma etching apparatus.

3. A method for cleaning a plasma etching apparatus according to claim 1, wherein the fluorine-based gas is selected from the group consisting of CF₄, SF₆ and NF₃.

4. A method for cleaning a plasma etching apparatus according to claim 2, wherein the fluorine-based gas is selected from the group consisting of CF₄, SF₆ and NF₃.

5. A method for cleaning a plasma etching apparatus according to claim 1, wherein an etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂.

6. A method for cleaning a plasma etching apparatus according to claim 2, wherein an etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂.

7. A method for cleaning a plasma etching apparatus according to claim 3, wherein an etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂.

8. A method for cleaning a plasma etching apparatus comprising the steps of:
performing plasma etching using a gas containing BCl₃ as an etching gas in a chamber;
replacing the etching gas in the chamber with Cl₂ or a mixed gas of Cl₂ and a fluorine-based gas after the plasma etching; and
generating plasma from the Cl₂ or the mixed gas of Cl₂ and the fluorine-based gas.

9. A method for cleaning a plasma etching apparatus according to claim 8, wherein a method selected from the group consisting of an RIE etching method, an ICP etching method, an ECR etching method, a helicon wave etching method, a helical resonance etching method and a pulse modulation etching method is adopted in the plasma etching apparatus.

10. A method for cleaning a plasma etching apparatus according to claim 8, wherein the fluorine-based gas is selected from the group consisting of CF₄, SF₆ and NF₃.

11. A method for cleaning a plasma etching apparatus according to claim 9, wherein the fluorine-based gas is selected from the group consisting of CF₄, SF₆ and NF₃.

12. A method for cleaning a plasma etching apparatus according to claim 8, wherein the etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂.

13. A method for cleaning a plasma etching apparatus according to claim 9, wherein the etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂.

14. A method for cleaning a plasma etching apparatus according to claim 10, wherein the etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂.

15. A method for cleaning a plasma etching apparatus comprising the steps of:
performing plasma etching using a gas containing BCl₃ as an etching gas in a chamber;
replacing the etching gas in the chamber with a mixed gas of Cl₂ and a fluorine-based gas or Cl₂ after the plasma etching; and
generating plasma from the mixed gas of Cl₂ and the fluorine-based gas or the Cl₂ before a plasma etching using a gas that is inhibited from generating plasma by BOₓ as an etching gas.

16. A method for cleaning a plasma etching apparatus according to claim 15, wherein a method selected from the group consisting of an RIE etching method, an ICP etching method, an ECR etching method, a helicon wave etching method, a helical resonance etching method and a pulse modulation etching method is adopted in the plasma etching apparatus.

17. A method for cleaning a plasma etching apparatus according to claim 15, wherein the fluorine-based gas is selected from the group consisting of CF₄, SF₆ and NF₃.

18. A method for cleaning a plasma etching apparatus according to claim 16, wherein the fluorine-based gas is selected from the group consisting of CF₄, SF₆ and NF₃.

19. A method for cleaning a plasma etching apparatus according to claim 15, wherein the etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂.

20. A method for cleaning a plasma etching apparatus according to claim 16, wherein the etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂.

21. A method for cleaning a plasma etching apparatus according to claim 17, wherein the etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂.

22. A method for cleaning a plasma etching apparatus comprising the steps of:
performing plasma etching using a gas containing BCl₃ as an etching gas in a chamber;
replacing the etching gas in the chamber with Cl₂ or a mixed gas of Cl₂ and a fluorine-based gas after the plasma etching; and
generating plasma from the Cl₂ or the mixed gas of Cl₂ and the fluorine-based gas before performing plasma etching using a gas containing SF₆ as an etching gas.

23. A method for cleaning a plasma etching apparatus according to claim 22, wherein a method selected from the group consisting of an RIE etching method, an ICP etching method, an ECR etching method, a helicon wave etching method, a helical resonance etching method and a pulse modulation etching method is adopted in the plasma etching apparatus.

24. A method for cleaning a plasma etching apparatus according to claim 22, wherein the fluorine-based gas is selected from the group consisting of CF₄, SF₆ and NF₃.

25. A method for cleaning a plasma etching apparatus according to claim 23, wherein the fluorine-based gas is selected from the group consisting of CF₄, SF₆ and NF₃.

26. A method for cleaning a plasma etching apparatus according to claim 22, wherein the etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂.

27. A method for cleaning a plasma etching apparatus according to claim 23, wherein the etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂.

28. A method for cleaning a plasma etching apparatus according to claim 24, wherein the etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂.

29. A method for cleaning a plasma etching apparatus including a chamber, said method comprising the steps of:
filling the chamber with Cl₂ or a mixed gas of Cl₂ and a fluorine-based gas; and
generating plasma from the Cl₂ or the mixed gas of Cl₂ and the fluorine-based gas,
wherein a part of the chamber is made from quartz, and a surface of the quartz is at least partly exposed to an inside of the chamber,
wherein BOₓ is adhered to the surface of the quartz at least partly exposed to the inside of the chamber as a residue.

30. A method for cleaning a plasma etching apparatus according to claim 29, wherein a method selected form the group consisting of an RIE etching method, an ICP etching method, an ECR etching method, a helicon wave etching method, a helical resonance etching method and a pulse modulation etching method is adopted in the plasma etching apparatus.

31. A method for cleaning a plasma etching apparatus according to claim 29, wherein the fluorine-based gas is selected from the group consisting of CF₄, SF₆ and NF₃.

32. A method for cleaning a plasma etching apparatus according to claim 30, wherein the fluorine-based gas is selected from the group consisting of CF₄, SF₆ and NF₃.

33. A method for cleaning a plasma etching apparatus according to claim 29, wherein an etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂.

34. A method for cleaning a plasma etching apparatus according to claim 30, wherein an etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂.

35. A method for cleaning a plasma etching apparatus according to claim 31, wherein an etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂.

36. A method for cleaning a plasma etching apparatus including a chamber, said method comprising the steps of:
performing plasma etching using a gas containing BCl₃ as an etching gas in the chamber;
replacing the etching gas in the chamber with a mixed gas of Cl₂ and a fluorine-based gas or Cl₂ after the plasma etching; and
generating plasma from the mixed gas of Cl₂ and the fluorine-based gas or the Cl₂,
wherein a part of the chamber is made from quartz, and a surface of the quartz is at least partly exposed to an inside of the chamber.

37. A method for cleaning a plasma etching apparatus according to claim 36, wherein a method selected from the group consisting of an RIE etching method, an ICP etching method, an ECR etching method, a helicon wave etching method, a helical resonance etching method and a pulse modulation etching method is adopted in the plasma etching apparatus.

38. A method for cleaning a plasma etching apparatus according to claim 36, wherein the fluorine-based gas is selected from the group consisting of CF₄, SF₆ and NF₃.

39. A method for cleaning a plasma etching apparatus according to claim 37, wherein the fluorine-based gas is selected from the group consisting of CF₄, SF₆ and NF₃.

40. A method for cleaning a plasma etching apparatus according to claim 36, wherein the etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂.

41. A method for cleaning a plasma etching apparatus according to claim 37, wherein the etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂.

42. A method for cleaning a plasma etching apparatus according to claim 38, wherein the etching gas is replaced with Cl₂ or a mixed gas of Cl₂ and a fluorine-based gas each of which is added with O₂, and plasma is generated from Cl₂ or the mixed gas of Cl₂ and the fluorine-based gas each of which is added with O₂.

43. A method for cleaning a plasma etching apparatus including a chamber, said method comprising the steps of:
performing plasma etching using a gas containing BCl₃ as an etching gas in the chamber;
replacing the etching gas in the chamber with Cl₂ or a mixed gas of Cl₂ and a fluorine-based gas after the plasma etching; and
generating plasma from the Cl₂ or the mixed gas of Cl₂ and the fluorine-based gas before performing plasma etching using a gas that is inhibited from generating plasma by BOₓ as an etching gas,
wherein a part of the chamber is made from quartz, and a surface of the quartz is at least partly exposed to an inside of the chamber.

44. A method for cleaning a plasma etching apparatus according to claim 43, wherein a method selected from the group consisting of an RIE etching method, an ICP etching method, an ECR etching method, a helicon wave etching method, a helical resonance etching method and a pulse modulation etching method is adopted in the plasma etching apparatus.

45. A method for cleaning a plasma etching according to claim 43, wherein the fluorine-based gas is selected from the group consisting of CF₄, SF₆ and NF₃.

46. A method for cleaning a plasma etching apparatus according to claim 44, wherein the fluorine-based gas is selected from the group consisting of CF₄, SF₆ and NF₃.

47. A method for cleaning a plasma etching apparatus according to claim 43, wherein the etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂.

48. A method for cleaning a plasma etching apparatus according to claim 44, wherein the etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂.

49. A method for cleaning a plasma etching apparatus according to claim 45, wherein the etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂.

50. A method for cleaning a plasma etching apparatus including a chamber, said method comprising the steps of:
performing plasma etching using a gas containing BCl₃ as an etching gas in the chamber;
replacing the etching gas in the chamber with Cl₂ or a mixed gas of Cl₂ and a fluorine-based gas after the plasma etching; and
generating plasma from the Cl₂ or the mixed gas of Cl₂ and the fluorine-based gas before performing plasma etching using a gas containing SF₆ as an etching gas,
wherein a part of the chamber is made from quartz, and a surface of the quartz is at least partly exposed to an inside of the chamber.

51. A method for cleaning a plasma etching apparatus according to claim 50, wherein a method selected from the group consisting of an RIE etching method, an ICP etching method, an ECR etching method, a helicon wave etching method, a helical resonance etching method and a pulse modulation etching method is adopted in the plasma etching apparatus.

52. A method for cleaning a plasma etching apparatus according to claim 50, wherein the fluorine-based gas is selected from the group consisting of CF₄, SF₆ and NF₃.

53. A method for cleaning a plasma etching apparatus according to claim 51, wherein the fluorine-based gas is selected from the group consisting of CF₄, SF₆ and NF₃.

54. A method for cleaning a plasma etching apparatus according to claim 50, wherein the etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂.

55. A method for cleaning a plasma etching apparatus according to claim 51, wherein the etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂.

56. A method for cleaning a plasma etching apparatus according to claim 52, wherein the etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂.

57. A method for plasma etching comprising the steps of:
performing plasma etching a conductive film using a gas containing BCl₃ gas as an etching gas in a chamber;
replacing the etching gas in the chamber with Cl₂ or a mixed gas of Cl₂ and a fluorine-based gas after the plasma etching; and
generating a plasma from the Cl₂ or the mixed gas of Cl₂ and the fluorine-based gas before performing plasma etching using a gas that is inhibited from generating plasma by BOₓ as an etching gas.

58. A method for plasma etching according to claim 57, wherein a method selected from the group consisting of an RIE etching method, an ICP etching method, an ECR etching method, a helicon wave etching method, a helical resonance etching method and a pulse modulation etching method is adopted in the plasma etching apparatus.

59. A method for plasma etching according to claim 57, wherein the fluorine-based gas is selected from the group consisting of CF₄, SF₆ and NF₃.

60. A method for plasma etching according to claim 58, wherein the fluorine-based gas is selected from the group consisting of CF₄, SF₆ and NF₃.

61. A method for plasma etching according to claim 57, wherein the etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂.

62. A method for plasma etching according to claim 58, wherein the etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂.

63. A method for plasma etching according to claim 59, wherein the etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂.

64. A method for plasma etching comprising the steps of:
performing plasma etching using a gas containing BCl₃ gas as an etching gas in a chamber;
replacing the etching gas in the chamber with Cl₂ or a mixed gas of Cl₂ and a fluorine-based gas after the plasma etching;
generating plasma from the Cl₂ or the mixed gas of Cl₂ and the fluorine-based gas; and
performing plasma etching using a gas containing SF₆ gas as an etching gas.

65. A method for plasma etching according to claim 64, wherein a method selected from the group consisting of an RIE etching method, an ICP etching method, an ECR etching method, a helicon wave etching method, a helical resonance etching method and a pulse modulation etching method is adopted in the plasma etching apparatus.

66. A method for plasma etching according to claim 64, wherein the fluorine-based gas is selected from the group consisting of CF₄, SF₆ and NF₃.

67. A method for plasma etching according to claim 65, wherein the fluorine-based gas is selected from the group consisting of CF₄, SF₆ and NF₃.

68. A method for plasma etching according to claim 64, wherein the etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂.

69. A method for plasma etching according to claim 65, wherein the etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂.

70. A cleaning method for plasma etching apparatus according to claim 66, wherein the etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂.

71. A method for plasma etching using a plasma etching apparatus including a chamber, said method comprising the steps of:
performing plasma etching using a gas containing BCl₃ as an etching gas in the chamber;
replacing the etching gas in the chamber with Cl₂ or a mixed gas of Cl₂ and a fluorine-based gas after the plasma etching;
generating plasma from Cl₂ or the mixed gas of Cl₂ and the fluorine-based gas; and
performing plasma etching using a gas that is inhibited from generating plasma by BOₓ as an etching gas,
wherein a part of the chamber is made from quartz, and a surface of the quartz is at least partly exposed to an inside of the chamber.

72. A method for plasma etching according to claim 71, wherein a method selected from the group consisting of an RIE etching method, an ICP etching method, an ECR etching method, a helicon wave etching method, a helical resonance etching method and a pulse modulation etching method is adopted in the plasma etching apparatus.

73. A method for plasma etching according to claim 71, wherein the fluorine-based gas is selected from the group consisting of CF₄, SF₆ and NF₃.

74. A method for plasma etching according to claim 72, wherein the fluorine-based gas is selected from the group consisting of CF₄, SF₆ and NF₃.

75. A method for plasma etching according to claim 71, wherein the etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂.

76. A method for plasma etching according to claim 72, wherein the etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂.

77. A method for plasma etching according to claim 74, wherein the etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂.

78. A method for plasma etching using a plasma etching apparatus including a chamber, said method comprising the steps of:
performing plasma etching using a gas containing BCl₃ as an etching gas in the chamber;
replacing the etching gas in the chamber with Cl₂ or a mixed gas of Cl₂ and a fluorine-based gas after the plasma etching;
generating plasma from the Cl₂ or the mixed gas of Cl₂ and the fluorine-based gas; and
performing plasma etching using a gas containing SF₆ gas as etching gas,
wherein a part of the chamber is made from quartz, and a surface of the quartz is at least partly exposed to an inside of the chamber.

79. A method for plasma etching according to claim 78, wherein a method selected from the group consisting of an RIE etching method, an ICP etching method, an ECR etching method, a helicon wave etching method, a helical resonance etching method and a pulse modulation etching method is adopted in the plasma etching apparatus.

80. A method for plasma etching according to claim 78, wherein the fluorine-based gas is selected from the group consisting of CF₄, SF₆ and NF₃.

81. A method for plasma etching according to claim 79, wherein the fluorine-based gas is selected from the group consisting of CF₄, SF₆ and NF₃.

82. A method for plasma etching according to claim 78, wherein the etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂.

83. A method for plasma etching according to claim 79, wherein the etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂.

84. A method for plasma etching according to claim 80, wherein the etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂.

85. A method for manufacturing a semiconductor device comprising the steps of:
laminating a first conductive film and a second conductive film in sequence over an island shape semiconductor film with a gate insulating film interposed therebetween;
etching the first conductive film and the second conductive film to form a first shape of the first conductive film and a first shape of the second conductive film, respectively, by using a first etching gas;
replacing the first etching gas in a chamber with Cl₂ or a mixed gas of Cl₂ and a fluorine-based gas wherein BOₓ is adhered to an inside of the chamber as a residue; and
generating plasma from the Cl₂ or the mixed gas of Cl₂ and the fluorine-based gas to remove the BOₓ; and
anisotropic etching the first shape of the first conductive film and the first shape of the second conductive film to form a second shape of the first conductive film and a second shape of the second conductive film, respectively.

86. A method for manufacturing a semiconductor device according to claim 85, wherein a width of the second shape of the first conductive film is longer than that of the second shape of the second conductive film in a channel length direction.

87. A method for manufacturing a semiconductor device according to claim 85, wherein a method selected from the group consisting of an RIE etching method, an ICP etching method, an ECR etching method, a helicon wave etching method, a helical resonance etching method and a pulse modulation etching method is adopted in the plasma etching apparatus.

88. A method for manufacturing a semiconductor device according to claim 86, wherein a method selected from the group consisting of an RIE etching method, an ICP etching method, an ECR etching method, a helicon wave etching method, a helical resonance etching method and a pulse modulation etching method is adopted in the plasma etching apparatus.

89. A method for manufacturing a semiconductor device according to claim 85, wherein the fluorine-based gas is selected from the group consisting of CF₄, SF₆ and NF₃.

90. A method for manufacturing a semiconductor device according to claim 86, wherein the fluorine-based gas is selected from the group consisting of CF₄, SF₆ and NF₃.

91. A method for manufacturing a semiconductor device according to claim 87, wherein the fluorine-based gas is selected from the group consisting of CF₄, SF₆ and NF₃.

92. A method for manufacturing a semiconductor device according to claim 85, wherein an etching gas is replaced with Cl₂ or a mixed gas of Cl₂ and a fluorine-based gas, or Cl₂ gas each of which is added with O₂, and plasma is generated from the Cl₂ or the mixed gas of Cl₂ and the fluorine-based gas each of which is added with O₂ to remove the BOₓ.

93. A method for manufacturing a semiconductor device according to claim 86, wherein the etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂ to remove the BOₓ.

94. A method for manufacturing a semiconductor device according to claim 87, wherein the etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂ to remove the BOₓ.

95. A method for manufacturing a semiconductor device according to claim 89, wherein the etching gas is replaced with Cl₂ or a mixed gas of Cl₂ and a fluorine-based gas each of which is added with O₂, and plasma is generated from the Cl₂ or the mixed gas of Cl₂ and the fluorine-based gas each of which is added with O₂ to remove the BOₓ.
